(19) United States
(12) Patent Application Publication
(10) Pub. No.: US 2010/0116337 A1
(43) Pub. Date: May 13, 2010

(54) Tandem Module Photovoltaic Devices Including An Organic Module

(75) Inventor: David Eaglesham, Perrysburg, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/572,172

(22) Filed: Oct. 1, 2009

Related U.S. Application Data
(60) Provisional application No. 61/136,814, filed on Oct. 6, 2008.

(51) Int. Cl. H01L 31/00; H01L 31/0272; H01L 51/48

(52) U.S. Cl. 136/260; 136/252; 438/82; 438/84; 257/E51.012; 257/E31.008

(57) ABSTRACT

A tandem module photovoltaic cell can include an organic module in parallel with a semiconductor module.

### CLAIM FOR PRIORITY

This application claims priority under 35 U.S.C. §119(e) to Provisional U.S. Patent Application Ser. No. 61/136,814 filed on Oct. 6, 2008, which is hereby incorporated by reference.

### TECHNICAL FIELD

This invention relates to tandem organic devices.

### BACKGROUND

Photovoltaic devices can be composed of two linked solar cells with different absorption characteristics to use a wider range of the solar spectrum. These tandem cells can be highly efficient, and have been commercialized in concentrator cells and for satellites. However, tandem cells have not been successfully commercialized in flat-panel photovoltaics.

Organic photovoltaics, based on carbon, are flexible, lightweight, and potentially less expensive than traditional solar cells. The main drawback is that organic photovoltaic cells are nowhere near as efficient at converting light into electricity as silicon cells.

### DESCRIPTION OF DRAWINGS

FIG. 1 is a schematic of a photovoltaic tandem device having sub-modules.

FIG. 2 is a schematic of a photovoltaic tandem device having inorganic and organic sub-modules.

### DETAILED DESCRIPTION

A high-efficiency tandem photovoltaic device can include a front sub-module and a rear sub-module. The rear sub-module can be wired in parallel to the front sub-module. The rear sub-module can be voltage-matched to the front sub-module.

The device may have various optional features. For example, the front sub-module may include a superstrate cell. The front sub-module may include CdTe. The front sub-module may include an alloy of CdTe. The front sub-module may include one or more CdTe alloys, where Cd is at least partially replaced by Zn, Hg, Mg or Mn. The front sub-module may include one or more CdTe alloys, where Te is at least partially replaced by S, Se or O. The front sub-module may include Si. The front sub-module may include CIGS. The rear sub-module may include an organic cell. The front sub-module may include a glass-glass laminate.

A high-efficiency tandem photovoltaic device may also include a front sub-module and an organic rear sub-module. The organic rear sub-module can be wired in parallel to the front sub-module, where the organic rear sub-module is voltage-matched to the front sub-module.

The device may have various optional features. For example, the front sub-module may include a superstrate cell. The front sub-module may include CdTe. The front sub-module may include an alloy of CdTe. The front sub-module may include one or more CdTe alloys, where Cd is at least partially replaced by Zn, Hg, Mg or Mn. The front sub-module may include one or more CdTe alloys, where Te is at least partially replaced by S, Se or O. The front sub-module may include Si. The front sub-module may include CIGS. The organic rear sub-module may include an organic cell. The front sub-module may include a glass-glass laminate.

A method of making a high-efficiency tandem photovoltaic device may include wiring a front sub-module and a rear sub-module in parallel. The rear sub-module may include an organic rear sub-module. The rear sub-module may be voltage-matched to the front sub-module. The front sub-module may include a superstrate cell. The front sub-module may include CdTe. The front sub-module may include Si. The rear sub-module may include an organic cell.

Multi-junction photovoltaics, tandem or triple-junction, have been responsible for all of the record high-efficiency cells produced in research labs for 30 years. They have been commercialized as concentrator cells and for satellites but have never been successfully implemented in flat-panel photovoltaics of the kind that make up 95% of the market for two reasons.

Tandem photovoltaics require current-matching between the two cells, which greatly limits the choice of materials-combinations that can be used. The most critical factor in determining the efficiency of a photovoltaic tandem cell (hereinafter called a tandem cell) is the need to match the short circuit currents of both the top and bottom cells. The total current from a tandem cell can be no greater than the smallest current generated by either the top or bottom cell.

For commercial success, stringent cost requirements are imposed on the second of the two devices (the “rear wheel”). The second device must produce enough electricity to pay for itself (in $/W) despite giving away much of the available power to the front device. By definition, any rear-wheel device with useful cost/W would deliver still lower cost/W if it were implemented without the front device. Thus multi-junction devices are used only in concentrator applications where the cost of the cell is a small component of the total device cost.

Photovoltaic cells are semiconductors that convert electromagnetic energy, such as light or solar radiation, directly to electricity. These semiconductors are characterized by solid crystalline structures that have energy bands gaps between their valence electron bands and their conduction electron bands, so that free electrons cannot ordinarily exist or remain in these band gaps. However, when light is absorbed by the materials that characterize the photovoltaic cells, electrons that occupy low-energy states are excited and jump the band gap to unoccupied higher energy states.

Thus, when electrons in the valence band of a semiconductor absorb sufficient energy from photons of solar radiation, they jump the band gap to the higher energy conduction band. Electrons excited to higher energy states leave behind them unoccupied low-energy positions which are referred to as holes. These holes may shift from atom to atom in the crystal lattice and the holes act as charge carriers, in the valence bond, as do free electrons in the conduction band, to contribute to the crystal's conductivity. Most of the photons that are absorbed in the semiconductor produce such electron-hole pairs. These electron-hole pairs generate photocurrent and, in the presence of a built-in field, the photovoltage of the solar cells. Electron-hole pairs produced by the light would eventually recombine, and convert to heat or a photon the energy initially used to jump the band gap, unless prevented from doing so. To prevent this phenomenom, a local electric field is created in the semiconductor by doping or interfacing dissimilar materials to produce a space charge layer. The space charge layer separates the holes and electrons for use as charge carriers. Once separated, these collected hole and electron charge carriers produce a space charge that results in a voltage across the junction, which is the photovoltage. If these separated hole and charge carriers are allowed to flow through an external load, they would constitute a photocurrent. It is well known that photon energies in excess of the threshold energy gap or band gap between the valence and conduction bands are dissipated as heat; thus they are wasted and do no useful work. Specifically, there is a fixed quantum of potential energy difference across the band gap in the semiconductor. For an electron in the lower energy valence band to be excited to jump the band gap to the higher energy conduction band, it must absorb a sufficient quantum of energy from an absorbed photon with a value at least equal to the potential energy difference across the band gap. A semiconductor is transparent to radiation with photon energy less than the band gap. But if the electron absorbs more than the threshold quantum of energy, e.g., from a larger energy photon, it can jump the band gap.

If the semiconductor is designed with a larger band gap to increase the photovoltage and reduce energy loss caused by thermalization of hot carriers, then the photons from lower energy radiation will not be absorbed. Materials, such as silicon with a band gap of 1.1 eV, are relatively inexpensive and are considered to be good solar energy conversion semiconductors for conventional single junction solar cells.

A photovoltaic cell can have multiple layers. The multiple layers can include a bottom layer that can be a transparent conductive layer, a capping layer, a window layer, an absorber layer and a top layer. Each layer can be deposited at a different deposition station of a manufacturing line with a separate deposition gas supply and a vacuum-sealed deposition chamber at each station as required. The substrate can be transferred from deposition station to deposition station via a rolling conveyor until all of the desired layers are deposited. Additional layers can be added using other techniques such as sputtering. Electrical conductors can be connected to the top and the bottom layers respectively to collect the electrical energy produced when solar energy is incident onto the absorber layer. A top substrate layer can be placed on top of the top layer to form a sandwich and complete the photovoltaic cell.

The bottom layer can be a transparent conductive layer, and can be, for example, a transparent conductive oxide such as tin oxide or tin oxide doped with fluorine.

The bottom layer of a photovoltaic cell can be a transparent conductive layer. A thin capping layer can be on top of and at least covering the transparent conductive layer in part. The next layer deposited can be the first semiconductor layer, which can serve as a window layer and can be thinner based on the use of a transparent conductive layer and the capping layer. The next layer deposited can be the second semiconductor layer, which serves as the absorber layer. Other layers, such as layers including dopants, can be deposited or otherwise placed on the substrate throughout the manufacturing process as needed. The substrate can be glass. A photovoltaic cell can be part of a submodule, which includes greater than 50 cells. The submodule can also include greater than 80 cells. The submodule can also include greater than 100 cells.

The transparent conductive layer can be a transparent conductive oxide, such as a metallic oxide like tin oxide, which can be doped with, for example, Zn or Cd. This layer can be deposited between the front contact and the first semiconductor layer, and can have a resistivity sufficiently high to reduce the effects of pinholes in the first semiconductor layer. Pinholes in the first semiconductor layer can result in shunt formation between the second semiconductor layer and the first contact resulting in a drain on the local field surrounding the pinhole. A small increase in the resistance of this pathway can dramatically reduce the area affected by the shunt.

The first semiconductor layer can serve as a window layer for the second semiconductor layer. The first semiconductor layer can be thinner than the second semiconductor layer. By being thinner, the first semiconductor layer can allow greater penetration of the shorter wavelengths of the incident light to the second semiconductor layer.

A system for generating electrical energy can include a transparent conductive layer on a substrate, a first semiconductor layer including a wide bandgap semiconductor, a second semiconductor layer, and an interfacial layer in contact with a second semiconductor layer. The interfacial layer can maintain the chemical potential of the second semiconductor layer at a controlled level in the interfacial region of the second semiconductor layer, a first electrical connection connected to the transparent conductive layer, and a second electrical connection connected to the back metal contact. The interfacial layer can be between the second semiconductor layer and a back metal contact..

A system for generating electrical energy can include a first electrode connected to the transparent conductive layer and a second electrode connected to the back metal contact. The first electrode can be substantially transparent to light having an energy between 1 and 3 eV, and the second electrode can be largely transparent to light with energy below the bandgap of the second semiconductor. A system for generating electrical energy can include two or more photovoltaic devices positioned in tandem.

Organic photovoltaics are widely researched but have not been successfully commercialized. Organics promise very low cost/m² for the material itself and have been intensively pursued by many companies and research groups. Organic photovoltaics are built from thin films, typically 100 nm, of organic semiconductors such as polymers and small-molecule compounds like polyphenylene vinylene, copper phthalocyanine (a blue or green organic pigment) and carbon fullerenes. These devices differ from inorganic semiconductor photovoltaics in that they do not rely on the large built in electric field of a PN junction to separate the electrons and holes created when photons are absorbed. The active region of an organic device consists of two materials, one which acts as an electron donor and the other as an acceptor. When a photon is converted into an electron hole pair, typically in the donor material, the charges tend to remain bound in the form of an exciton, and are separated when the exciton diffuses to the donor-acceptor interface.

Organic photovoltaics suffer from three flaws; low efficiency, poor stability, and expensive packaging requirements.

Efficiencies for organic cells have typically run ˜2-4%. Even if the cost of the organic material and its processing are low enough to bring the cost/W to a competitive point, a 4% efficiency is inadequate to pay for the balance-of-systems cost including mounting, wiring, inverter, and so on associated with the PV system.

Stability of the organics under solar illumination is generally very poor, with degradation over weeks and months rather than years. This is largely inherent to the nature of organic molecules, which are prone to charge-transfer reactions that lead to bond-breakage when exposed to photons that are significantly larger than the material band-gap (e.g., >1.5 eV).

Organics are sensitive to moisture and oxygen and require a hermetic package, preferably a glass/glass laminate package. This means that despite inherently lower materials cost for the organic cell, the cost of an organic module (per m2) is the same as any other TF module, i.e., being mostly glass and plastic laminate.

A tandem-module involves manufacturing two sub-modules, each of which is separately scribed and bussed. The two sub-modules are then sandwiched together and wired in parallel to make a single tandem-module. This addresses the problem of current-matching in the cell: it is now only necessary to match the voltages on the two modules which can be done by module design as well as by materials selection. Techniques which can be used to optimize and tune the voltage on a sub-module include selection of the cell size at which the sub-module is scribed, selection of the bussing approach (single- or double-bussed sub-modules for lower- or higher-voltage) as well as materials-selection. The matching of voltages in a tandem-module panel is thus much easier than matching the current in a tandem-cell cell.

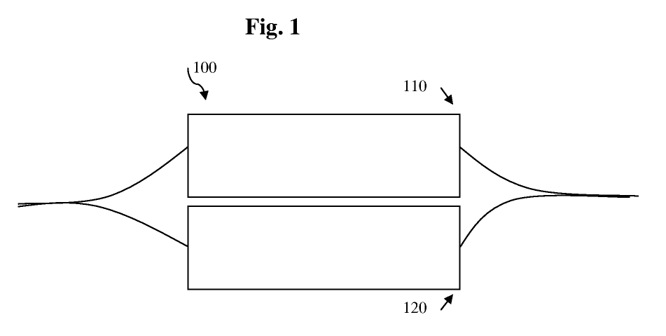

Referring to FIG. 1, a photovoltaic tandem-module 100 can include a “front wheel” sub-module 110 wired in parallel with a “rear wheel” sub-module 120. As described above, the “front wheel” sub-module 110 can be voltage-matched to the “rear wheel” sub-module 120.

This concept does not, however, solve the cost challenge facing tandems. Thus, the present invention proposes the use of organics for the “rear wheel” device. This addresses all of the weaknesses of organics. The front device excludes all of the harmful high-energy photons that are responsible for light-induced degradation of the device. The front device also pays for the glass-glass laminate and for the balance-of-system costs since these are already present in the single-junction module and the array. The final device would no longer involve the installation and deployment of a 3% module, just the implementation of a more expensive process to convert an 11% module into a 14% module. The organic sub-module now only has to hit a target cost-per-W for the material itself and the sub-module process.

The use of an organic rear-wheel with either a-Si or CdTe as the front-wheel is especially interesting because they work well in “superstrate” configuration. With a “substrate”-oriented inorganic device (like CIGS) the organic would have to have a gap wider than that of the inorganic and would not be protected by the absorption in the inorganic. In addition, an inorganic such as a-Si or CdTe with a band-gap near 1.1-1.5 eV is well-suited to this problem since a good fraction of the available solar flux is at an energy that is not absorbed.

The front wheel inorganic sub-module can include a CdTe. The front wheel inorganic sub-module can include an alloy of CdTe. The front wheel inorganic sub-module can include a CdTe alloy wherein Cd is at least partially replaced by Zn, Hg, Mg or Mn. The front wheel inorganic sub-module can include CdTe alloys wherein Te is at least partially replaced by S, Se or O.

The front wheel inorganic sub-module can include a-Si. Amorphous silicon cells may include polycrystalline silicon based solar cells that have a silicon nitride gate dielectric/amorphous silicon semiconductor interface. See for example U.S. Pat. No. 5,273,920, U.S. Pat. No. 5,281,546, M. J. Keeves, A. Turner, U. Schubert, P. A. Basore, M. A. Green, 20^{th} EU Photovoltaic Solar Energy Conf., Barcelona (2005) p 1305-1308; P. A. Basore, 4^{th} World Conf. Photovoltaic Energy Conversion, Hawaii (2006) p 2089-2093, which are incorporated by reference herein.

The front wheel inorganic sub-module can include a copper indium diselenide layer, which can be a copper indium gallium diselenide (CIGS) layer, or a precursor layer capable of being converted to a CIGS layer, such as an oxide layer. The front wheel inorganic sub-module can include additional layers of material, including, for example, a transparent conductive oxide layer, such as a zinc oxide or tin oxide, or a semiconductor layer, such as cadmium sulfide. See, for example, “Nanoparticle Oxides Precursor Inks for Thin Film Copper Indium Gallium Selenide (Copper Indium Gallium Diselenide) Solar Cells,” Kapur, Vijay K. et al., Mat. Res. Soc. Proc. Vol. 668, (2001) ppH2.6.1-H2.6.7, which is incorporated by reference in its entirety.

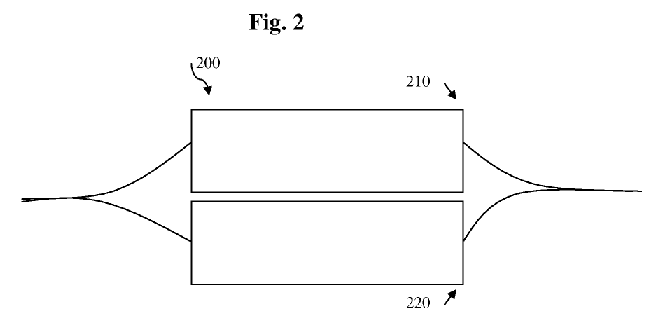

Referring to FIG. 2, a photovoltaic tandem-module 200 can include a “front wheel” CIGS, a-Si, or CdTe sub-module 210 wired in parallel with a “rear wheel” organic sub-module 220. The “rear wheel” organic sub-module 220 can be a polymer or small-molecule compound like polyphenylene vinylene, copper phthalocyanine, and carbon fullerenes. As described above, the “front wheel” CIGS, a-Si, or CdTe sub-module 210 can be voltage-matched to the “rear wheel” organic sub-module 220.

A number of embodiments have been described. Nevertheless, it will be understood that various modifications may be made without departing from the spirit and scope of the claimed device. For example, the semiconductor layers can include a variety of other materials, as can the materials used for the buffer layer and the capping layer. Accordingly, other embodiments are within the scope of the following claims.

What is claimed is:

1. A high-efficiency tandem photovoltaic device comprising:
a front sub-module; and
a rear sub-module, wired in parallel to the front sub-module, the rear sub-module being voltage-matched to the front module.

2. The device of claim 1, wherein the front sub-module includes a superstrate cell.

3. The device of claim 1, wherein the front sub-module includes CdTe.

4. The device of claim 1, wherein the front sub-module includes an alloy of CdTe.

5. The device of claim 4, wherein the front sub-module includes CdTe alloys, wherein Cd is at least partially replaced by Zn, Hg, Mg or Mn.

6. The device of claim 4, wherein the front sub-module includes CdTe alloys, wherein Te is at least partially replaced by S, Se or O.

7. The device of claim 1, wherein the front sub-module includes Si.

8. The device of claim 1, wherein the front sub-module includes CIGS.

9. The device of claim 1, wherein the rear sub-module includes an organic cell.

10. The device of claim 1, wherein the front sub-module includes a glass-glass laminate.

11. A high-efficiency tandem photovoltaic device comprising:
a front sub-module; and
an organic rear sub-module, wired in parallel to the front sub-module, the organic rear sub-module being voltage-matched to the front sub-module.

12. The device of claim 11, wherein the front sub-module includes a superstrate cell.

13. The device of claim 11, wherein the front sub-module includes CdTe.

14. The device of claim 11, wherein the front sub-module includes an alloy of CdTe.

15. The device of claim 14, wherein the front sub-module includes CdTe alloys, wherein Cd is at least partially replaced by Zn, Hg, Mg or Mn.

16. The device of claim 14, wherein the front sub-module includes CdTe alloys, wherein Te is at least partially replaced by S, Se or O.

17. The device of claim 11, wherein the front sub-module includes Si.

18. The device of claim 11, wherein the front sub-module includes CIGS.

19. The device of claim 11, wherein the organic rear sub-module includes an organic cell.

20. The device of claim 11, wherein the front sub-module includes a glass-glass laminate.

21. A method of making a high-efficiency tandem photovoltaic device comprising:
wiring a front sub-module and a rear sub-module in parallel, wherein the rear sub-module is voltage-matched to the front sub-module.

22. The method of claim 21, wherein the front sub-module includes a superstrate cell.

23. The method of claim 21, wherein the front sub-module includes CdTe.

24. The method of claim 21, wherein the front sub-module includes Si.

25. The method of claim 21, wherein the rear sub-module includes an organic cell.
